(19) United States
(12) Patent Application Publication
(10) Pub. No.: US 2024/0351865 A1
(43) Pub. Date: Oct. 24, 2024

(54) MANUFACTURING METHOD OF MEMS DEVICE

(71) Applicant: Xintec Inc., Taoyuan City (TW)

(72) Inventors: Jiun-Yen LAI, Taoyuan City (TW); Wei-Luen SUEN, Taoyuan City (TW); Ming-Chung CHUNG, Taoyuan City (TW); Chih-Wei LIU, Zhubei City (TW)

(21) Appl. No.: 18/622,059

(22) Filed: Mar. 29, 2024

Related U.S. Application Data
(60) Provisional application No. 63/497,422, filed on Apr. 20, 2023.

(51) Int. Cl. B81C 1/00

(52) U.S. Cl. CPC B81C 1/00825; B81C 2201/013; B81C 2201/0143; B81C 2201/0146; B81C 2201/0159

(57) ABSTRACT

A manufacturing method of a micro electro mechanical system (MEMS) device includes forming a buffer protection layer on a semiconductor structure, wherein the semiconductor structure includes a wafer, a MEMS membrane, and an isolation layer between the wafer and the MEMS membrane, and the buffer protection layer is located in a slit of the MEMS membrane and on a surface of the MEMS membrane facing away from the isolation layer; etching the wafer to form a cavity such that a portion of the isolation layer is exposed though the cavity; etching the portion of the isolation layer; and removing the buffer protection layer.

### CROSS-REFERENCE TO RELATED APPLICATIONS

This application claims priority to U.S. Provisional Application Ser. No. 63/497,422, filed Apr. 20, 2023 which is herein incorporated by reference.

### BACKGROUND

### Field of Invention

The present disclosure relates to a manufacturing method of a micro electro mechanical system (MEMS) device.

### Description of Related Art

Silicon-on-insulator (SOI) wafers can be used to manufacture products with micro electro mechanical systems (MEMS). Generally speaking, an SOI wafer can include a wafer and a MEMS membrane on the wafer. During the manufacturing process, in order to avoid damage to the MEMS membrane due to bending, the MEMS membrane can be attached to a carrier before performing an etching process on the wafer.

Since the higher deflection of the MEMS membrane is beneficial to the performance of sound pressure level (SPL), the thickness of the MEMS membrane is limited, and the development trend in this field is to increase the number of the slits of the MEMS membrane and the cavity length of the wafer to reduce the stiffness of the MEMS membrane. However, when the carrier is removed from such an SOI wafer, external force easily causes damage to the MEMS membrane, thereby reducing product yield.

### SUMMARY

One aspect of the present disclosure provides a manufacturing method of a micro electro mechanical system (MEMS) device.

According to some embodiments of the present disclosure, a manufacturing method of a micro electro mechanical system (MEMS) device includes forming a buffer protection layer on a semiconductor structure, wherein the semiconductor structure includes a wafer, a MEMS membrane, and an isolation layer between the wafer and the MEMS membrane, and the buffer protection layer is located in a slit of the MEMS membrane and on a surface of the MEMS membrane facing away from the isolation layer; etching the wafer to form a cavity such that a portion of the isolation layer is exposed though the cavity; etching the portion of the isolation layer; and removing the buffer protection layer.

In some embodiments, the buffer protection layer is in direct contact with the MEMS membrane.

In some embodiments, the buffer protection layer extends from the surface of the MEMS membrane into the slit of the MEMS membrane.

In some embodiments, the buffer protection layer covers the entire surface of the MEMS membrane.

In some embodiments, the buffer protection layer is a polyimide film.

In some embodiments, the manufacturing method of the MEMS device further includes grinding a surface of the wafer facing away from the isolation layer to reduce a thickness of the wafer.

In some embodiments, the manufacturing method of the MEMS device further includes forming a patterned photoresist layer on the surface of the wafer.

In some embodiments, etching the wafer to form the cavity further includes etching a portion of the wafer not covered by the photoresist layer.

In some embodiments, the manufacturing method of the MEMS device further includes after etching the portion of the wafer not covered by the photoresist layer, removing the photoresist layer.

In some embodiments, the manufacturing method of the MEMS device further includes after etching said portion of the isolation layer and before removing the buffer protection layer, attaching a surface of the wafer facing away from the isolation layer to an adhesive tape.

In some embodiments, the manufacturing method of the MEMS device further includes bonding the semiconductor structure to a carrier by using a temporary bonding layer, such that the temporary bonding layer is located between the buffer protection layer and the carrier.

In some embodiments, the manufacturing method of the MEMS device further includes using a laser to focus on an interface between the temporary bonding layer and the carrier; removing the carrier; and removing the temporary bonding layer.

Another aspect of the present disclosure provides a manufacturing method of a micro electro mechanical system (MEMS) device.

According to some embodiments of the present disclosure, a manufacturing method of a micro electro mechanical system (MEMS) device includes forming a buffer protection layer on a semiconductor structure, wherein the semiconductor structure includes a wafer and a MEMS membrane, and the buffer protection layer is located in a slit of the MEMS membrane and on a surface of the MEMS membrane facing away from the wafer; bonding the semiconductor structure to a carrier by using a temporary bonding layer, such that the temporary bonding layer is located between the buffer protection layer and the carrier; etching the wafer to form a cavity; removing the carrier; removing the temporary bonding layer; and removing the buffer protection layer.

In some embodiments, the buffer protection layer is in direct contact with the MEMS membrane.

In some embodiments, the manufacturing method of the MEMS device further includes grinding a surface of the wafer facing away from the MEMS membrane to reduce a thickness of the wafer.

In some embodiments, the manufacturing method of the MEMS device further includes forming a patterned photoresist layer on the surface of the wafer.

In some embodiments, etching the wafer to form the cavity further includes etching a portion of the wafer not covered by the photoresist layer.

In some embodiments, the manufacturing method of the MEMS device further includes after etching the portion of the wafer not covered by the photoresist layer, removing the photoresist layer.

In some embodiments, the manufacturing method of the MEMS device further includes before removing the buffer protection layer, attaching a surface of the wafer facing away from the MEMS membrane to an adhesive tape.

In some embodiments, the manufacturing method of the MEMS device further includes using a laser to focus on an interface between the temporary bonding layer and the carrier.

In the aforementioned embodiments of the present disclosure, since the buffer protection layer is formed on the semiconductor structure to enable the buffer protection layer to be located in the slit of the MEMS membrane and on the surface of the MEMS membrane facing away from the isolation layer, the buffer protection layer can provide a supporting force during subsequent grinding and etching of the wafer. Furthermore, a temporary bonding layer and a carrier may be omitted based on process requirements. If the semiconductor structure is bonded to a carrier by using a temporary bonding layer, the buffer protection layer can protect the MEMS membrane from damage by external forces. Through the aforementioned design, the wafer may form a larger cavity, the MEMS membrane may have more slits and a smaller thickness to reduce the stiffness of the MEMS membrane and to improve the deflection of the MEMS membrane, which are beneficial to the performance of sound pressure level (SPL). Accordingly, the aforementioned manufacturing method of the MEMS device can improve product yield and product competitiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 11 are cross-sectional views at intermediate stages of a manufacturing method of a micro electro mechanical system (MEMS) device according to one embodiment of the present disclosure.

FIGS. 12 to 15 are cross-sectional views at intermediate stages of a manufacturing method of a MEMS device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

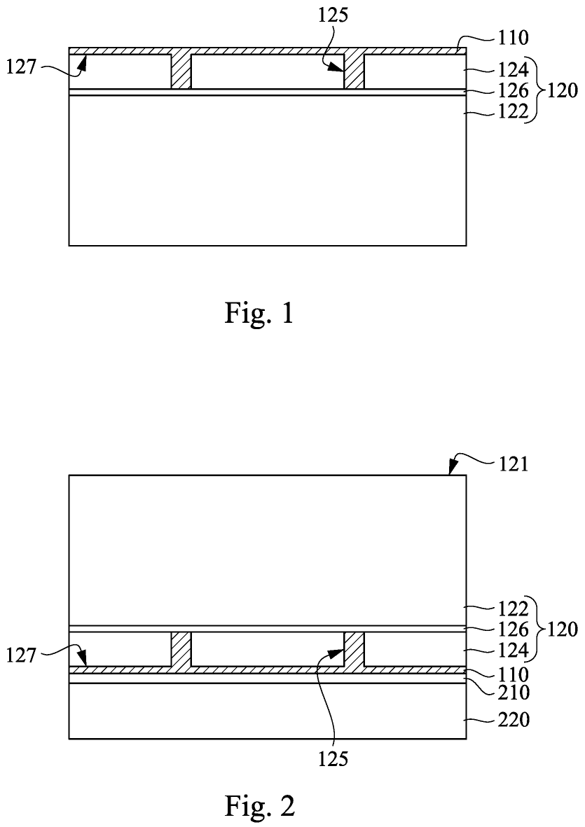

FIGS. 1 to 11 are cross-sectional views at intermediate stages of a manufacturing method of a micro electro mechanical system (MEMS) device 100 (see FIG. 10) according to one embodiment of the present disclosure. As shown in FIG. 1, a semiconductor structure 120 includes a wafer 122, a micro electro mechanical system (MEMS) membrane 124, and an isolation layer 126. The isolation layer 126 is located between the wafer 122 and the MEMS membrane 124. The MEMS membrane 124 has a slit 125. The semiconductor structure 120 may be a silicon-on-insulator (SOI) wafer. In some embodiments, the material of the wafer 122 and the material of the MEMS membrane 124 may include silicon, and the material of the MEMS membrane 124 may include oxide and metal, but the present disclosure is not limited in this regard.

First, a buffer protection layer 110 may be formed on the semiconductor structure 120, such that the buffer protection layer 110 is located in the slit 125 of the MEMS membrane 124 and on a surface 127 of the MEMS membrane 124 facing away from the isolation layer 126 and the wafer 122. In this embodiment, the buffer protection layer 110 may be a polyimide (PI) film. The buffer protection layer 110 may be in direct contact with the MEMS membrane 124, and the buffer protection layer 110 may extend from the surface 127 of the MEMS membrane 124 into the slit 125 of the MEMS membrane 124. Moreover, the buffer protection layer 110 may cover the entire surface 127 of the MEMS membrane 124.

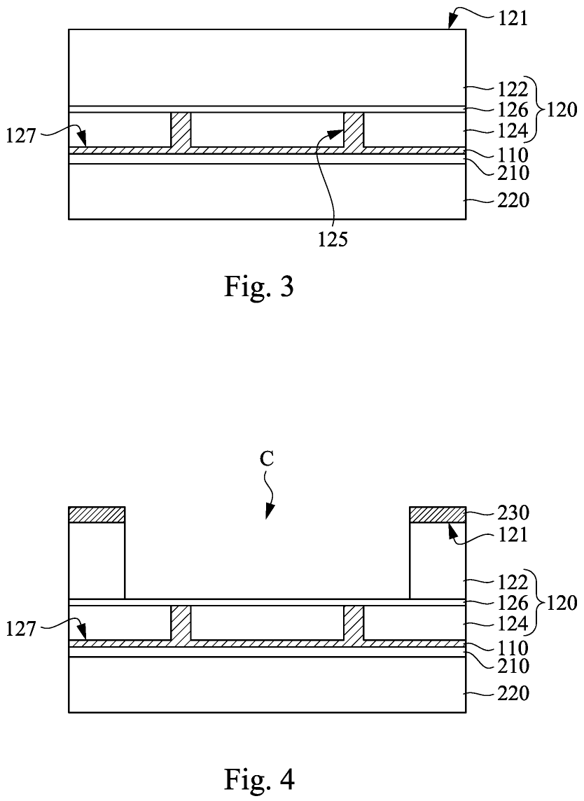

As shown in FIG. 2, after the buffer protection layer 110 is formed on the semiconductor structure 120, a temporary bonding layer 210 may be used to bond the semiconductor structure 120 to a carrier 220, such that the temporary bonding layer 210 is located between the buffer protection layer 110 and the carrier 220. The material of the carrier 220 may be, but not limited to glass. Thereafter, a grinding treatment may be performed on a surface 121 of the wafer 122 facing away from the isolation layer 126 and the MEMS membrane 124 to reduce the thickness of the wafer 122, as shown in FIG. 3. In this step, the carrier 220 and the buffer protection layer 110 can provide a supporting force when grinding the wafer 122.

As shown in FIG. 3 and FIG. 4, after grinding the wafer 122, the wafer 122 may be etched to form a cavity C such that a portion of the isolation layer 126 is exposed though the cavity C. In the step of etching the wafer 122 to form the cavity C, a patterned photoresist layer 230 may be formed on the surface 121 of the wafer 122, and then the portion of the wafer 122 not covered by the photoresist layer 230 is etched. In this step, the carrier 220 and the buffer protection layer 110 can provide a supporting force when etching the wafer 122. The length of the cavity C may be greater than 4 mm, such as in a range from 4.6 mm to 8.6 mm.

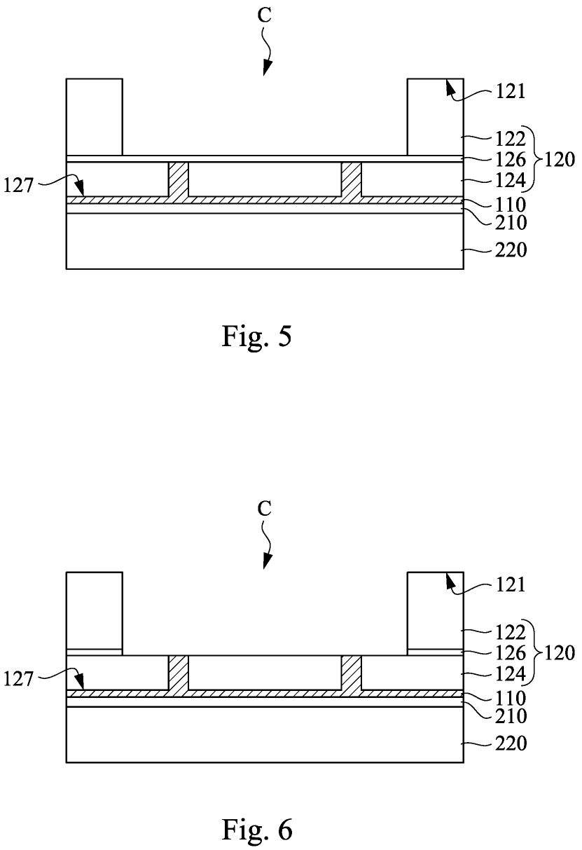

As shown in FIG. 5 and FIG. 6, after etching the portion of the wafer 122 not covered by the photoresist layer 230 (see FIG. 4), the photoresist layer 230 can be removed. Thereafter, the isolation layer 126 can be etched to remove the portion of the isolation layer 126 exposed through the cavity C, thereby obtaining the structure of FIG. 6.

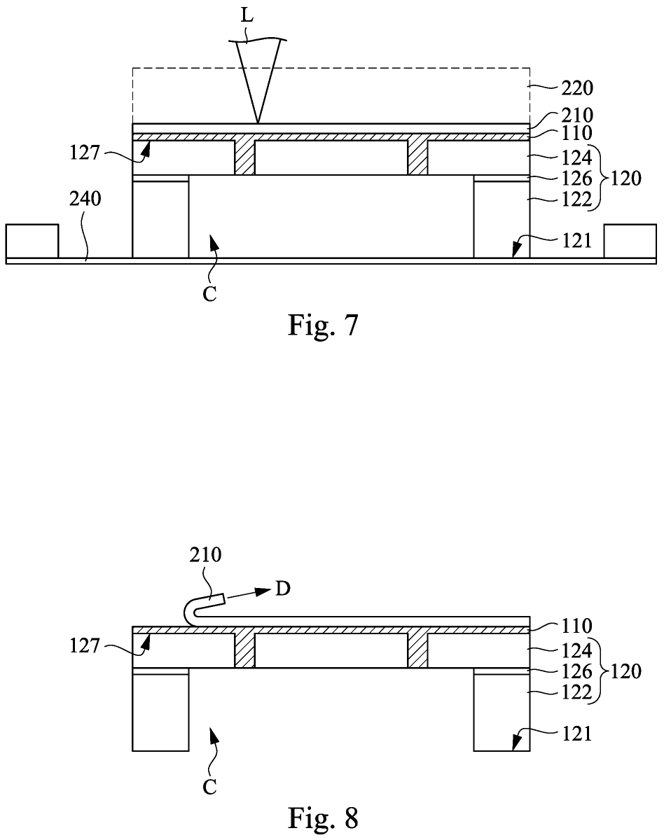

As shown in FIG. 7, after etching the portion of the isolation layer 126 exposed through the cavity C and before removing the buffer protection layer 110, the surface 121 of the wafer 122 facing away from the isolation layer 126 and the MEMS membrane 124 can be attached to an adhesive tape 240. The adhesive tape 240 is surrounded by an iron frame. Thereafter, a laser L is used to focus on an interface between the temporary bonding layer 210 and the carrier 220, such that the stickiness of the temporary bonding layer 210 disappears. As a result, the carrier 220 may be removed.

As shown in FIG. 8, after the carrier 220 is removed, the temporary bonding layer 210 is exposed and can be removed along a direction D, such that the temporary bonding layer 210 is de-taped from the buffer protection layer 110 on the MEMS membrane 124. In the aforementioned steps of removing the carrier 220 and the temporary bonding layer 210, the buffer protection layer 110 can protect the MEMS membrane 124 from damage by external forces.

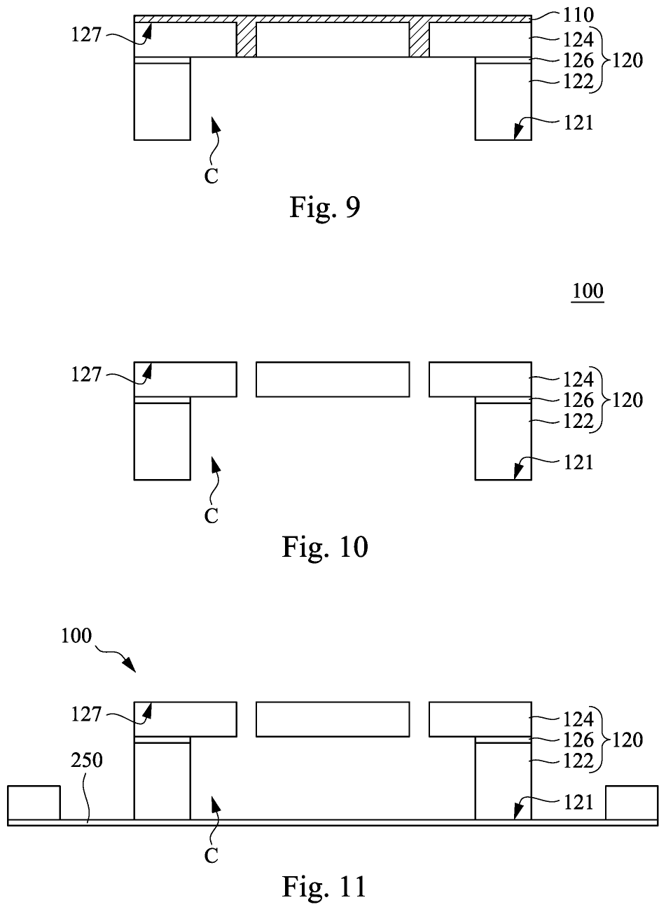

As shown in FIG. 9 and FIG. 10, after removing the temporary bonding layer 210, the buffer protection layer 110 is exposed. Thereafter, the buffer protection layer 110 can be removed to obtain the MEMS device 100 of FIG. 10. The MEMS device 100 may be applied to speakers, and has high sound pressure level (SPL).

In summary, since the buffer protection layer 110 is formed on the semiconductor structure 120 to enable the buffer protection layer 110 to be located in the slit 125 of the MEMS membrane 124 and on the surface 127 of the MEMS membrane 124 facing away from the wafer 122, the buffer protection layer 110 can provide a supporting force during subsequent grinding and etching of the wafer 122. When removing the carrier 220 and the temporary bonding layer 210, the buffer protection layer 110 can protect the MEMS membrane 124 from damage by external forces. Through the aforementioned design, the wafer 122 may form the larger cavity C, the MEMS membrane 124 may have more slits 125 and a smaller thickness to reduce the stiffness of the MEMS membrane 124 and to improve the deflection of the MEMS membrane 124, which are beneficial to the performance of sound pressure level (SPL). Accordingly, the aforementioned manufacturing method of the MEMS device 100 can improve product yield and product competitiveness.

As shown in FIG. 11, in a subsequent process, the MEMS device 100 may be attached to a dicing tape 250 for shipping and dicing. The dicing tape 250 may be surrounded by an iron frame.

It is to be noted that the connection relationships, the materials, and the advantages of the elements described above will not be repeated in the following description. In the following description, another embodiment of a manufacturing method of the MEMS device 100 (see FIG. 10) will be explained.

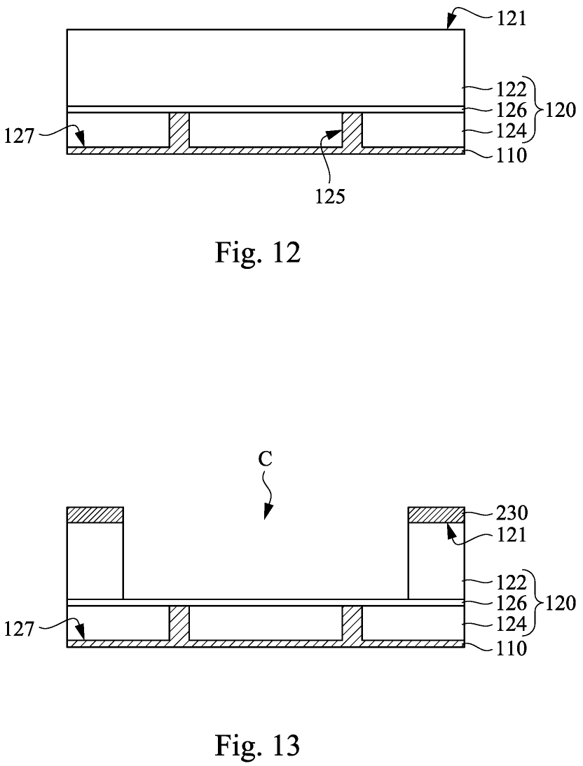

FIGS. 12 to 15 are cross-sectional views at intermediate stages of a manufacturing method of the MEMS device 100 (see FIG. 10) according to another embodiment of the present disclosure. As shown in FIG. 1 and FIG. 12, first, the buffer protection layer 110 may be formed on the semiconductor structure 120, such that the buffer protection layer 110 is located in the slit 125 of the MEMS membrane 124, and is located on the surface 127 of the MEMS membrane 124. Thereafter, a grinding treatment may be performed on the surface 121 of the wafer 122 to reduce the thickness of the wafer 122, as shown in FIG. 12. The difference between this embodiment and the embodiment of FIG. 3 is that the buffer protection layer 110 can provide enough supporting force when grinding the wafer 122, and thus there is no carrier 220 and temporary bonding layer 210 of FIG. 3. As a result, the bonding step of FIG. 2 can be omitted.

As shown in FIG. 13, after grinding the wafer 122, the wafer 122 may be etched to form the cavity C such that a portion of the isolation layer 126 is exposed though the cavity C. In the step of etching the wafer 122 to form the cavity C, the patterned photoresist layer 230 may be formed on the surface 121 of the wafer 122, and then the portion of the wafer 122 not covered by the photoresist layer 230 is etched. The difference between this embodiment and the embodiment of FIG. 4 is that only the buffer protection layer 110 provides a supporting force when etching the wafer 122, and there is no carrier 220 of FIG. 4 to provide a supporting force.

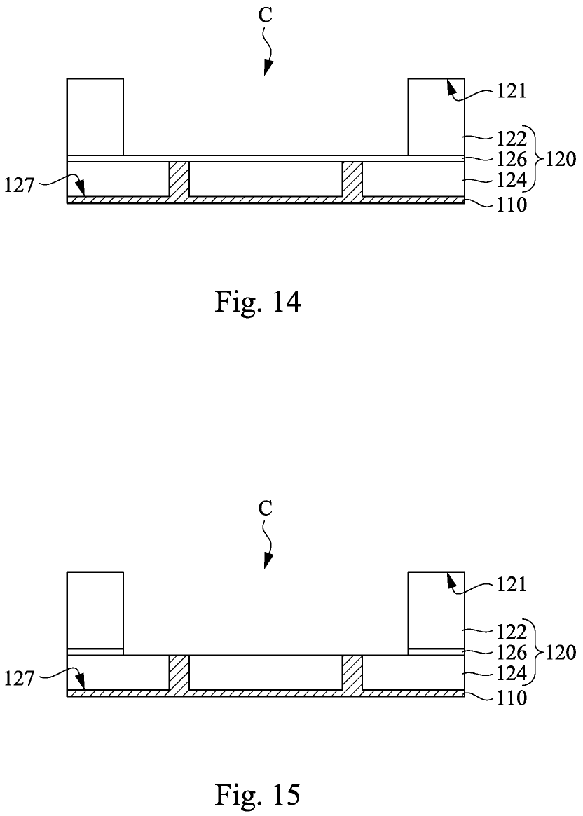

As shown in FIG. 14, after etching the wafer 122 to form the cavity C, the photoresist layer 230 can be removed. The difference between this embodiment and the embodiment of FIG. 5 is that there is no carrier 220 and temporary bonding layer 210 of FIG. 5.

As shown in FIG. 15, after removing the photoresist layer 230, the isolation layer 126 can be etched to remove the portion of the isolation layer 126 exposed through the cavity C. The difference between this embodiment and the embodiment of FIG. 6 is that there is no carrier 220 of FIG. 6 to provide a supporting force.

Since the buffer protection layer 110 can provide supporting forces when grinding the wafer 122 and etching the wafer 122, the aforementioned temporary bonding layer 210 and carrier 220 may be omitted based on process requirements. Accordingly, the steps of FIGS. 2 and 7 to 9 can be decreased to save material cost and process time.

In addition, the subsequent steps after the step of FIG. 15 are the steps of FIG. 10 and FIG. 11 in order. In other words, after the portion of the solation layer 126 exposed through the cavity C is etched, the buffer protection layer 110 can be removed to obtain the MEMS device 100 of FIG. 10.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a micro electro mechanical system (MEMS) device, comprising:
forming a buffer protection layer on a semiconductor structure, wherein the semiconductor structure includes a wafer, a MEMS membrane, and an isolation layer between the wafer and the MEMS membrane, and the buffer protection layer is located in a slit of the MEMS membrane and on a surface of the MEMS membrane facing away from the isolation layer;
etching the wafer to form a cavity such that a portion of the isolation layer is exposed though the cavity;
etching said portion of the isolation layer; and
removing the buffer protection layer.

2. The manufacturing method of the MEMS device of claim 1, wherein the buffer protection layer is in direct contact with the MEMS membrane.

3. The manufacturing method of the MEMS device of claim 1, wherein the buffer protection layer extends from the surface of the MEMS membrane into the slit of the MEMS membrane.

4. The manufacturing method of the MEMS device of claim 1, wherein the buffer protection layer covers the entire surface of the MEMS membrane.

5. The manufacturing method of the MEMS device of claim 1, wherein the buffer protection layer is a polyimide film.

6. The manufacturing method of the MEMS device of claim 1, further comprising:
grinding a surface of the wafer facing away from the isolation layer to reduce a thickness of the wafer.

7. The manufacturing method of the MEMS device of claim 6, further comprising:
forming a patterned photoresist layer on the surface of the wafer.

8. The manufacturing method of the MEMS device of claim 7, wherein etching the wafer to form the cavity further comprises:
etching a portion of the wafer not covered by the photoresist layer.

9. The manufacturing method of the MEMS device of claim 8, further comprising:
after etching the portion of the wafer not covered by the photoresist layer, removing the photoresist layer.

10. The manufacturing method of the MEMS device of claim 1, further comprising:
after etching said portion of the isolation layer and before removing the buffer protection layer, attaching a surface of the wafer facing away from the isolation layer to an adhesive tape.

11. The manufacturing method of the MEMS device of claim 1, further comprising:
bonding the semiconductor structure to a carrier by using a temporary bonding layer, such that the temporary bonding layer is located between the buffer protection layer and the carrier.

12. The manufacturing method of the MEMS device of claim 11, further comprising:
using a laser to focus on an interface between the temporary bonding layer and the carrier;
removing the carrier; and
removing the temporary bonding layer.

13. A manufacturing method of a micro electro mechanical system (MEMS) device, comprising:
forming a buffer protection layer on a semiconductor structure, wherein the semiconductor structure includes a wafer and a MEMS membrane, and the buffer protection layer is located in a slit of the MEMS membrane and a surface of the MEMS membrane facing away from the wafer;
bonding the semiconductor structure to a carrier by using a temporary bonding layer, such that the temporary bonding layer is located between the buffer protection layer and the carrier;
etching the wafer to form a cavity;
removing the carrier;
removing the temporary bonding layer; and
removing the buffer protection layer.

14. The manufacturing method of the MEMS device of claim 13, wherein the buffer protection layer is in direct contact with the MEMS membrane.

15. The manufacturing method of the MEMS device of claim 13, further comprising:
grinding a surface of the wafer facing away from the MEMS membrane to reduce a thickness of the wafer.

16. The manufacturing method of the MEMS device of claim 15, further comprising:
forming a patterned photoresist layer on the surface of the wafer.

17. The manufacturing method of the MEMS device of claim 16, wherein etching the wafer to form the cavity further comprises:
etching a portion of the wafer not covered by the photoresist layer.

18. The manufacturing method of the MEMS device of claim 17, further comprising:
after etching the portion of the wafer not covered by the photoresist layer, removing the photoresist layer.

19. The manufacturing method of the MEMS device of claim 13, further comprising:
before removing the buffer protection layer, attaching a surface of the wafer facing away from the MEMS membrane to an adhesive tape.

20. The manufacturing method of the MEMS device of claim 13, further comprising:
using a laser to focus on an interface between the temporary bonding layer and the carrier.
